(19) United States
(12) Patent Application Publication
(10) Pub. No.: US 2024/0387455 A1
(43) Pub. Date: Nov. 21, 2024

(54) SEMICONDUCTOR PACKAGE AND METHOD OF MANUFACTURING THE SAME

(71) Applicant: NHINC Co., Ltd., Bucheon-si (KR)

(72) Inventor: Yun Hwa CHOI, Busan (KR)

(73) Assignee: NHINC Co., Ltd., Bucheon-si (KR)

(21) Appl. No.: 18/416,845

(22) Filed: Jan. 18, 2024

(30) Foreign Application Priority Data
May 17, 2023 (KR) 10-2023-0063648

(51) Int. Cl. H01L 25/065; H01L 21/48; H01L 21/56; H01L 23/00; H01L 23/31; H01L 23/498; H01L 23/538

(52) U.S. Cl. CPC H01L 25/0655; H01L 21/4857; H01L 21/56; H01L 23/3107; H01L 23/49811; H01L 23/5383; H01L 24/32; H01L 24/37; H01L 24/40; H01L 24/45; H01L 24/48; H01L 2224/32225; H01L 2224/37124; H01L 2224/37144; H01L 2224/37147; H01L 2224/40227; H01L 2224/45124; H01L 2224/45144; H01L 2224/45147; H01L 2224/48227

(57) ABSTRACT

The present invention provides a semiconductor package including at least one first insulating substrate in which a first metal pattern layer and a first insulating layer are stacked; at least one first semiconductor component installed on the first insulating substrate and electrically connected to the first metal pattern layer; at least one second insulating substrate spaced apart from the first metal pattern layer by a regular distance, structurally bonded onto the first insulating layer of the first insulating substrate, and in which a second insulating layer and a second metal pattern layer are stacked; at least one second semiconductor component installed on the second insulating substrate and electrically connected to the second metal pattern layer; at least one lead frame terminal electrically connected to the first insulating substrate or the second insulating substrate; and a housing covering the first semiconductor component, the second semiconductor component, and a part of the lead frame terminal, wherein the thickness of the second metal pattern layer of the second insulating substrate is formed to be thinner than the thickness of the first metal pattern layer of the first insulating substrate so that installation of the second semiconductor components may be available.

### CROSS-REFERENCE TO RELATED PATENT APPLICATION

This application claims the benefit of Korean Patent Application No. 10-2023-0063648, filed on May 17, 2023, in the Korean Intellectual Property Office, the disclosure of which is incorporated herein in its entirety by reference.

### BACKGROUND OF THE INVENTION

### 1. Field of the Invention

The present invention relates to a semiconductor package and a method of manufacturing the same, and more particularly, to a semiconductor package and a method of manufacturing the same in which a thickness of an upper substrate is formed to be relatively thin in a multi-layer substrate structure and thereby, semiconductor components may be easily installed thereon.

### 2. Description of the Related Art

In general, a semiconductor package is manufactured in such a way that one or more semiconductor chips are installed on a lead frame or a printed circuit board and are sealed using sealing resin. Then, the semiconductor package is used after being installed on a mother board or a printed circuit board.

Meanwhile, there is a demand for miniaturized, light-weighted, and multi-function power devices applied to electronic equipment due to high speed, high capacity, and high density integration of electronic equipment.

In this regard, a power module package in which a plurality of power semiconductor chips and control semiconductor chips are integrated on one semiconductor chip is introduced.

For example, as illustrated in FIG. 1, a power module package according to the prior art has a structure where a first metal layer 11, a ceramic insulating layer 12, and a second metal layer 13 are stacked, wherein the second metal layer 13 is relatively thick generally having a thickness of 0.1 mm through 1.5 mm. Accordingly, there is a limit to narrow a gap between metal patterns by etching.

That is, it is not easy to install a power semiconductor chip 14 on the second metal layer 13 and a control semiconductor chip 16 having a relatively smaller installation area than that of the power semiconductor chip 14 on a third metal layer 15 that is separately formed from the second metal layer 13.

In this regard, there is a demand for the technology that forms a multi-layer substrate structure, enables installation of a control power semiconductor chip, and secures electrical stability.

### SUMMARY OF THE INVENTION

The present invention provides a semiconductor package and a method of manufacturing the same in which a thickness of an upper substrate is formed to be relatively thin in a multi-layer substrate structure and thereby, semiconductor components may be easily installed thereon without electrical leakage.

According to an aspect of the present invention, there is provided a semiconductor package including: at least one first insulating substrate in which a first metal pattern layer and a first insulating layer are stacked; at least one first semiconductor component installed on the first insulating substrate and electrically connected to the first metal pattern layer; at least one second insulating substrate spaced apart from the first metal pattern layer by a regular distance, structurally bonded onto the first insulating layer of the first insulating substrate, and in which a second insulating layer and a second metal pattern layer are stacked; at least one second semiconductor component installed on the second insulating substrate and electrically connected to the second metal pattern layer; at least one lead frame terminal electrically connected to the first insulating substrate or the second insulating substrate; and a housing covering the first semiconductor component, the second semiconductor component, and a part of the lead frame terminal, wherein the thickness of the second metal pattern layer of the second insulating substrate is formed to be thinner than the thickness of the first metal pattern layer of the first insulating substrate.

Here, the first insulating substrate may be formed in such a way that at least one first upper metal pattern layer, at least one first insulating layer, and at least one first lower metal pattern layer are stacked or at least one first insulating layer and at least one first upper metal pattern layer are stacked.

Here, the first insulating layer may be formed of a ceramic based material including Al₂O₃, AlN, or Si₃N₄.

Also, the first insulating substrate may be a direct bonded copper (DBC) substrate or an active metal brazing (AMB) substrate.

Also, the second insulating substrate may include at least one second insulating layer.

Also, the second metal pattern layer may be partially or entirely covered with a third protective insulating layer except for the area of the second metal pattern layer where the second semiconductor component is installed.

Also, the second insulating layer may include a via hole penetrated thereinto and the second metal pattern layer comprises a second upper metal pattern layer and a second low metal pattern layer which are connected to each other by a metal via formed in the via hole.

Here, the second semiconductor component may be installed on the second upper metal pattern layer and a fourth insulating layer may be formed between the first insulating layer and the second low metal pattern layer.

Here, the second insulating layer and the fourth insulating layer may be formed by using the same insulating material and thereby, are connected to each other

Also, the second insulating layer may be formed of FR4, FR5, or Bismaleimide Triazine (BT) resin applied to a printed circuit board (PCB).

Also, the first semiconductor component may be a power semiconductor chip of an insulated gate bipolar transistor (IGBT), a metal-oxide semiconductor field effect transistor (MOSFET), or diode.

Also, the second semiconductor component may be a gate drive integrated circuit (IC), a negative temperature coefficient (NTC) thermistor, or a resistance component.

Also, an electrical connecting member which is mainly formed of Au, Cu, or Al may be ultrasonic bonded to the second semiconductor component and the second metal pattern layer and are electrically connected to each other.

Also, an electrical connecting member which is a metal ingredient may be used to electrically connect the second semiconductor component to the second metal pattern layer but the electrical connecting member may be a lead frame terminal prepared on the second semiconductor component.

Also, the second semiconductor component may be a semiconductor bare chip and may include at least four metal pads) on the upper surface of the semiconductor bare chip for electrical connection.

Also, the first semiconductor component and the second metal pattern layer may be electrically connected to each other by an electrical connecting member.

Also, the first upper metal pattern layer and the second metal pattern layer may be electrically connected to each other by an electrical connecting member.

Also, the lead frame terminal may be bonded to the first insulating substrate or the second insulating substrate by soldering or sintering using a conductive adhesive interposed therebetween or by ultrasonic welding.

Also, some areas of the second insulating substrate may be spaced apart from the first upper metal pattern layer of the first insulating substrate by a regular distance.

Also, the entire thickness of the second insulating substrate may be thinner than the entire thickness of the first insulating substrate.

Also, the first insulating substrate may be partially or entirely exposed to the upper surface or the lower surface of the housing.

Here, pin-fins may be structurally connected to the first metal pattern layer included in the first insulating substrate which is exposed to the outside of the housing.

Also, the first semiconductor component and a part of the at least one second semiconductor component may be respectively bonded to the first insulating substrate and the second insulating substrate by using the same adhesive member interposed therebetween at the same temperature condition.

Also, after some areas of the first upper metal pattern layer of the first insulating substrate are removed, the second insulating substrate may be stacked on the first insulating layer which is exposed after being removed, and a circuit pattern of the second metal pattern layer may be formed by etching.

Also, the second insulating layer may be formed on the first insulating layer by using a screen printing method.

According to another aspect of the present invention, there is provided a method of manufacturing a semiconductor package including: preparing at least one first insulating substrate in which a first metal pattern layer and a first insulating layer are stacked; structurally bonding at least one second insulating substrate in which a second insulating layer and a second metal pattern layer are stacked onto the first insulating layer of the first insulating substrate by being spaced apart from the first metal pattern layer by a regular distance; respectively installing at least one first semiconductor component and at least one second semiconductor component on the first insulating substrate and the second insulating substrate and electrically connecting the first semiconductor component to the first metal pattern layer and the second semiconductor component to the second metal pattern layer; electrically connecting at least one lead frame terminal to the first insulating substrate or the second insulating substrate; and packaging a housing to cover the first semiconductor component, the second semiconductor component, and a part of the lead frame terminal, wherein the thickness of the second metal pattern layer of the second insulating substrate is thinner than the thickness of the first metal pattern layer of the first insulating substrate.

Here, the first insulating substrate may be formed in such a way that at least one first upper metal pattern layer, at least one first insulating layer, and at least one first lower metal pattern layer are stacked or at least one first insulating layer and at least one first upper metal pattern layer are stacked, and some areas of the second insulating substrate may be spaced apart from the first upper metal pattern layer of the first insulating substrate by a regular distance.

Here, the entire thickness of the second insulating substrate may be thinner than the entire thickness of the first insulating substrate.

Also, after some areas of the first upper metal pattern layer of the first insulating substrate are removed, the second insulating substrate may be stacked on the first insulating layer which is exposed after being removed, and a circuit pattern of the second metal pattern layer may be formed by etching.

Also, the second insulating layer may be formed on the first insulating layer by using a screen printing method.

Also, the first semiconductor component and a part of the at least one second semiconductor component may be respectively bonded to the first insulating substrate and the second insulating substrate by using the same adhesive member interposed therebetween at the same temperature condition.

### BRIEF DESCRIPTION OF THE DRAWINGS

The above and other features and advantages of the present invention will become more apparent by describing in detail exemplary embodiments thereof with reference to the attached drawings in which:

FIG. 1 illustrates a semiconductor package according to a prior art;

FIGS. 2A and 2B illustrate semiconductor packages according to an embodiment of the present invention;

FIGS. 3 and 4 are exploded views of a multi-layer substrate of the semiconductor package of FIGS. 2A and 2B;

FIG. 5 is a first example of the semiconductor package of FIGS. 2A and 2B;

FIG. 6 is a second example of the semiconductor package of FIGS. 2A and 2B;

FIG. 7 is a third example of the semiconductor package of FIGS. 2A and 2B;

FIG. 8 is a fourth example of the semiconductor package of FIGS. 2A and 2B; and

FIG. 9 is a flowchart illustrating a method of manufacturing a semiconductor package according to another embodiment of the present invention.

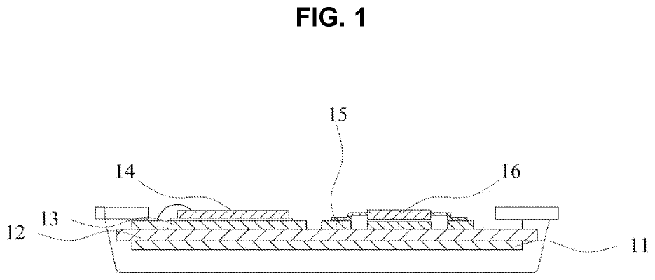

### DETAILED DESCRIPTION OF THE INVENTION

Hereinafter, embodiments of the present invention will be described in more detail with reference to the accompanying drawings.

A semiconductor package according to an embodiment of the present invention includes at least one first insulating substrate 110 in which a first metal pattern layer 111 and a first insulating layer 112 are stacked, at least one first semiconductor component 120 installed on the first insulating substrate 110 and electrically connected to the first metal pattern layer 111, at least one second insulating substrate 130 spaced apart from the first metal pattern layer 111 by a regular distance, structurally bonded onto the first insulating layer 112 of the first insulating substrate 110, and including a second insulating layer 131 and a second metal pattern layer 132 stacked thereon, at least one second semiconductor component 140 installed on the second insulating substrate 130 and electrically connected to the second metal pattern layer 132, at least one lead frame terminal 150 electrically connected to the first insulating substrate 110 or the second insulating substrate 130, and a housing 160 covering the first semiconductor component 120, the second semiconductor component 140, and a part of the lead frame terminal 150. Here, the thickness of the second metal pattern layer 132 of the second insulating substrate 130 may be formed to be thinner than the thickness of the first metal pattern layer 111 of the first insulating substrate 110 and thereby, installation of the second semiconductor component 140 may be available.

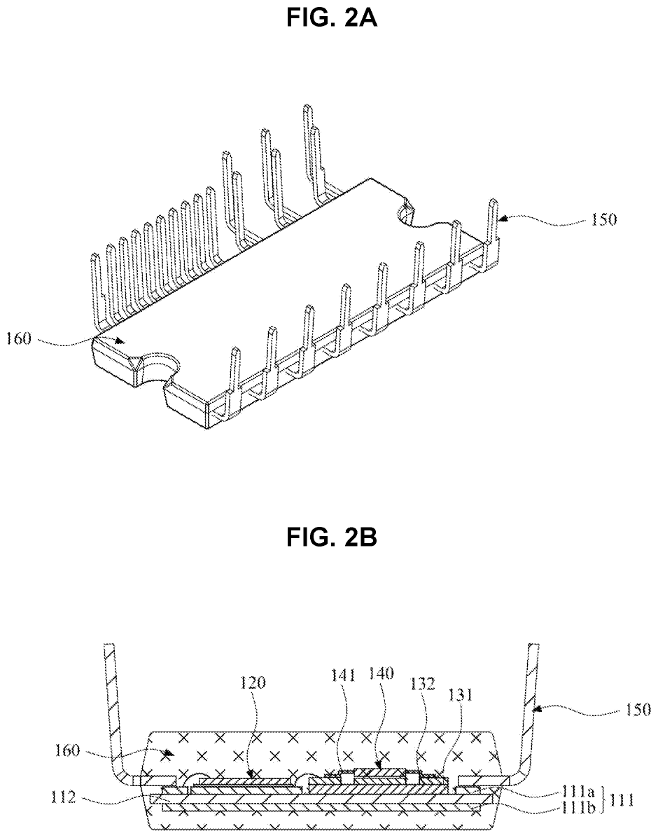

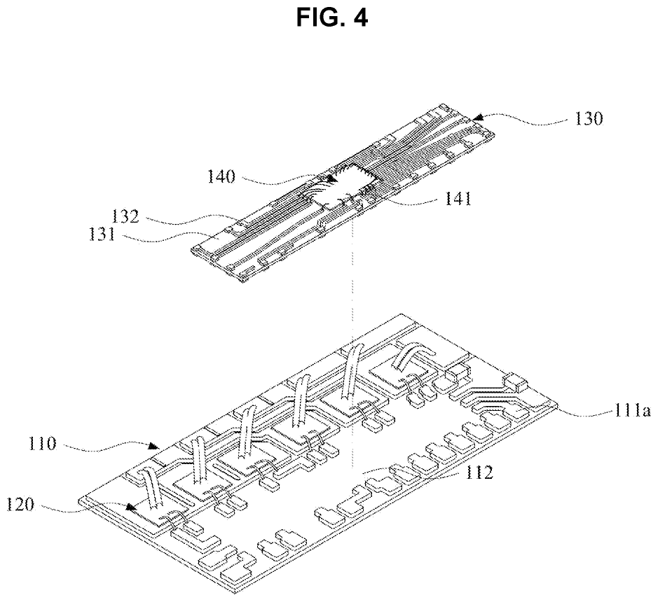

Hereinafter, the semiconductor package having a multi-layer substrate structure described above will be described in more detail with reference to FIGS. 2A through 8.

First, one or more first insulating substrates 110 are included as a lower substrate of a multi-layer substrate, that is, a base substrate. Referring to FIGS. 2A through 4, the first metal pattern layer 111 and the first insulating layer 112 are formed in a vertically stacked structure and the first semiconductor component 120 performing power switching is installed on the first metal pattern layer 111.

Here, as specifically illustrated in FIGS. 2A and 2B, the first insulating substrate 110 may be formed in such a way that at least one first upper metal pattern layer 111a, at least one first insulating layer 112, and at least one first lower metal pattern layer 111b are stacked or at least one first insulating layer 112 and at least one first upper metal pattern layer 111a are stacked.

Also, the first insulating layer 112 may be formed of a ceramic based material including Al₂O₃, AlN, or Si₃N₄.

Also, the first insulating substrate 110 may be a direct bonded copper (DBC) substrate or an active metal brazing (AMB) substrate.

Next, referring to FIGS. 2A through 4, one or more first semiconductor component 120 are included to be installed on the first insulating substrate 110 and electrically connected to the first metal pattern layer 111.

Here, the first semiconductor component 120 may be a power semiconductor chip of an insulated gate bipolar transistor (IGBT), a metal-oxide semiconductor field effect transistor (MOSFET), or diode which performs power switching.

Next, one or more second insulating substrate 130 are included as an upper substrate of a multi-layer substrate. Referring to FIGS. 2A through 4, the second insulating substrate 130 is spaced apart from the first metal pattern layer 111 by a regular distance, structurally bonded to the first insulating layer 112 of the first insulating substrate 110, and includes the second insulating layer 131 and the second metal pattern layer 132 stacked thereon.

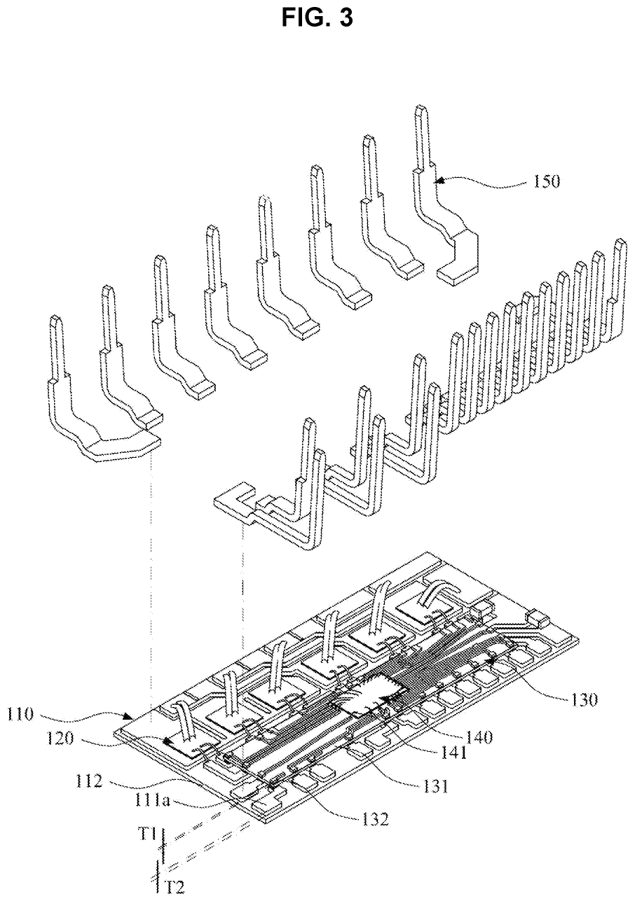

Here, referring to FIGS. 3 through 5, the thickness T1 of the second metal pattern layer 132 of the second insulating substrate 130 is thinner than the thickness T2 (for example, 0.1 mm through 1.5 mm) of the first metal pattern layer 111 of the first insulating substrate 110, that is, the first upper metal pattern layer 111a or the first lower metal pattern layer 111b. Accordingly, when a circuit pattern of the second metal pattern layer 132 is processed, a distance D1 of the circuit pattern may be narrower than a distance of a circuit pattern of the first metal pattern layer 111 by raising density. In this regard, the second semiconductor component 140 having a relatively smaller installation area that that of the first semiconductor component 120 may be installed on the second insulating substrate 130.

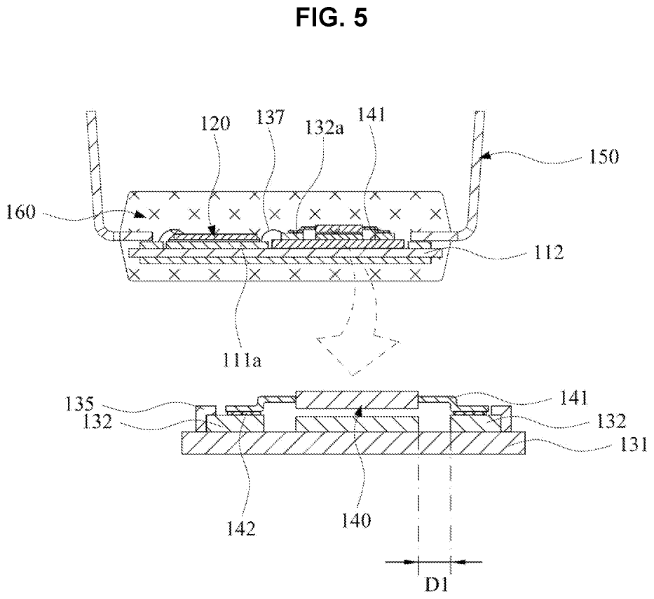

Also, referring to FIG. 5, the second metal pattern layer 132 is partially or entirely covered with a third protective insulating layer 135 except for the area of the second metal pattern layer 132 where the second semiconductor component 140 is installed so that a conductive adhesive 142 included while the second semiconductor component 140 is installed may be prevented from being spread and a leakage current may be blocked.

Also, the second insulating layer 131 may be formed using a material different from that of the first insulating layer 112 for matching and may be adhered onto the first insulating layer 112 in the form of paste or film.

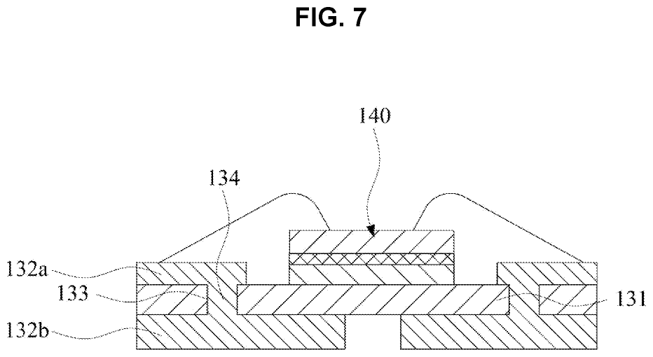

In addition, the second insulating substrate 130 may include at least one second insulating layer 131 and at least one second metal pattern layer 132. For example, as illustrated in FIG. 7, a via hole 133 may be formed by penetrating the second insulating layer 131 and the second metal pattern layer 132 may include a second upper metal pattern layer 132a and a second low metal pattern layer 132b which are connected to each other by a metal via 134 formed in the via hole 133.

For example, the metal via 134 forms the via hole 133 formed by penetrating using laser or a drill and is formed by using a plating method or a conductive paste so that the metal via 134 may electrically connect the second upper metal pattern layer 132a to the second low metal pattern layer 132b.

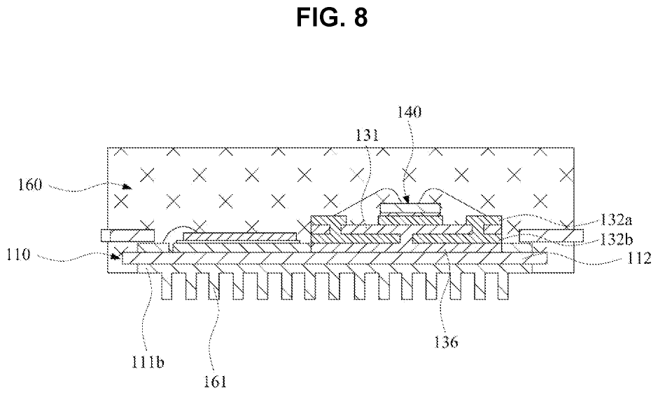

On the other hand, as illustrated in FIG. 8, the second semiconductor component 140 may be installed on the second upper metal pattern layer 132a by using a conductive adhesive and a fourth insulating layer 136 may be formed between the first insulating layer 112 and the second low metal pattern layer 132b.

Also, the second insulating layer 131 and the fourth insulating layer 136 are formed by using the same insulating material and thereby, may be structurally connected to each other.

In addition, the second insulating layer 131 is formed of FR4, FR5, or Bismaleimide Triazine (BT) resin which is BT based synthetic resin containing epoxy resin applied to a printed circuit board (PCB) and thereby, the via hole 133 may be easily processed by using laser or a drill.

Moreover, referring to FIG. 5, the first upper metal pattern layer 111a and the second upper metal pattern layer 132a of the second metal pattern layer 132 may be electrically connected to each other by using an electrical connecting member 137.

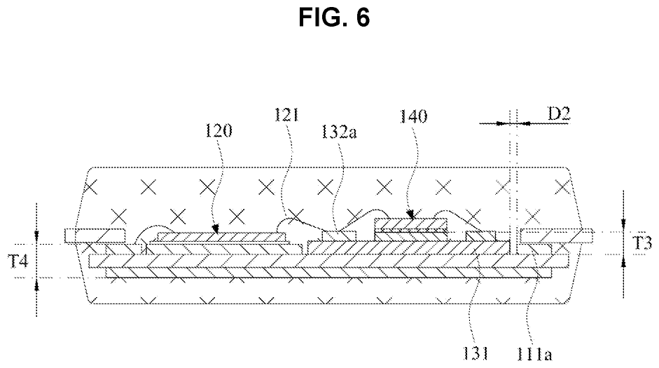

Also, referring to FIG. 6, some areas of the second insulating layer 131 of the second insulating substrate 130 are spaced apart from the first upper metal pattern layer 111a of the first insulating substrate 110 by a regular distance D2, for example, 1 μm through 10 mm, so that a leakage current between the first upper metal pattern layer 111a and the second semiconductor component 140 installed on the second insulating substrate 130 may be blocked and thereby, electrical stability may be secured.

In addition, the entire thickness T3 of the second insulating substrate 130 is thinner than the entire thickness T4 of the first insulating substrate 110 so that the total area of a multi-layer substrate may be reduced to be compact and a spare space may be secured for stacking the second insulating substrate 130 on the first insulating substrate 110.

Moreover, after some areas of the first upper metal pattern layer 111a of the first insulating substrate 110 are removed, the second insulating substrate 130 may be stacked on the first insulating layer 112 which is exposed after being removed, and a circuit pattern of the second metal pattern layer 132 may be formed by etching.

Also, the second insulating layer 131 may be formed on the exposed first insulating layer 112 by using a screen printing method.

Next, referring to FIGS. 2A through 4, one or more second semiconductor components 140 are included to be installed on the second insulating substrate 130 and electrically connected to the second metal pattern layer 132.

Here, the second semiconductor component 140 may be a gate drive integrated circuit (IC), a negative temperature coefficient (NTC) thermistor, or a resistance component which performs signal control.

Also, an electrical connecting member 141 which is a metal clip or a conductive wire mainly formed of Au, Cu, or Al may be ultrasonic bonded to the second semiconductor component 140 and the second metal pattern layer 132 and may be electrically connected to each other.

On the other hand, the electrical connecting member 141 which is a metal ingredient is used to electrically connect the second semiconductor component 140 to the second metal pattern layer 132 but such an electrical connecting member may be a lead frame terminal prepared on the second semiconductor component 140.

Also, the second semiconductor component 140 is a semiconductor bare chip (a separate IC cut on a wafer) and may include at least four metal pads (not illustrated) on the upper surface of the semiconductor bare chip for electrical connection through the electrical connecting member 141.

In addition, referring to FIG. 6, the first semiconductor component 120 and the second upper metal pattern layer 132a of the second metal pattern layer 132 may be electrically connected to each other by using an electrical connecting member 121 such as a conductive wire.

Moreover, the first semiconductor component 120 and a part of the at least one second semiconductor component 140 described above are respectively bonded to the first insulating substrate 110 and the second insulating substrate 130 by using the same adhesive member interposed therebetween at the same temperature condition and thereby, cracks which may be generated due to a difference in a thermal expansive coefficient may be minimized. More specifically, when a plurality of second semiconductor components 140 are installed on the second insulating substrate 130, the semiconductor bare chip may be bonded to the second insulating substrate 130 by using a conductive epoxy adhesive member containing Ag interposed therebetween and the other second semiconductor components 140 may be bonded to the second insulating substrate 130 by soldering or sintering.

Next, referring to FIGS. 2A, 2B and 5, one or more lead frame terminals 150 are included to be electrically connected to the first insulating substrate 110 or the second insulating substrate 130 and apply electrical signals.

Here, the lead frame terminals 150 may be bonded to the first insulating substrate 110 or the second insulating substrate 130 by soldering or sintering using a conductive adhesive interposed therebetween or by ultrasonic welding.

Next, referring to FIGS. 2A, 2B and 5, the housing 160 covers the first semiconductor component 120, the second semiconductor component 140, and a part of the lead frame terminal 150 so as to be electrically protected.

Meanwhile, referring to FIG. 8, the first insulating substrate 110, for example, the first lower metal pattern layer 111b, is partially or entirely exposed to the upper surface or the lower surface of the housing 160 and thereby, heat generated from the first insulating substrate 110 may be radiated to the outside. Also, pin-fins 161 are structurally connected to the first lower metal pattern layer 111b of the first metal pattern layer 111 included in the first insulating substrate 110 which is exposed to the outside of the housing 160 and thus, may contact a refrigerant that circulates in a cooling system (not illustrated) so that heat may be cooled down and thermal stability may be secured.

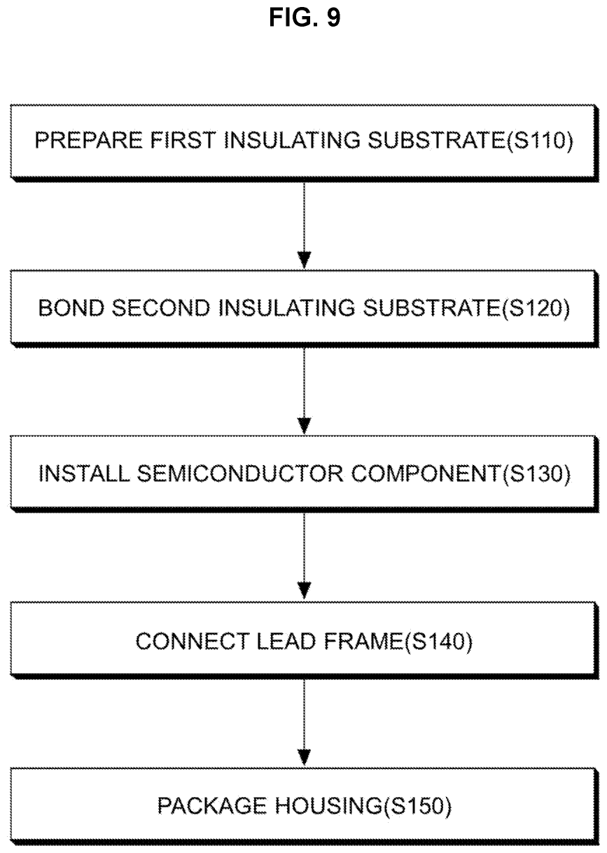

FIG. 9 is a flowchart illustrating a method of manufacturing a semiconductor package according to another embodiment of the present invention. Referring to FIG. 9, the method of manufacturing the semiconductor package described above includes preparing at least one first insulating substrate 110 in which the first metal pattern layer 111 and the first insulating layer 112 are stacked, in operation S110, structurally bonding at least one second insulating substrate 130 in which the second insulating layer 131 and the second metal pattern layer 132 are stacked onto the first insulating layer 112 of the first insulating substrate 110 by being spaced apart from the first metal pattern layer 111 by a regular distance, in operation S120, respectively installing at least one first semiconductor component 120 and at least one second semiconductor component 140 on the first insulating substrate 110 and the second insulating substrate 130 and electrically connecting the first semiconductor component 120 to the first metal pattern layer 111 and the second semiconductor component 140 to the second metal pattern layer 132, in operation S130, electrically connecting at least one lead frame terminal 150 to the first insulating substrate 110 or the second insulating substrate 130, in operation S140, and packaging the housing 160 to cover the first semiconductor component 120, the second semiconductor component 140, and a part of the lead frame terminal 150, in operation S150.

Here, referring to FIG. 3, the thickness T1 of the second metal pattern layer 132 of the second insulating substrate 130 is thinner than the thickness T2 (for example, 0.1 mm through 1.5 mm) of the first metal pattern layer 111 of the first insulating substrate 110, that is, the first upper metal pattern layer 111a or the first lower metal pattern layer 111b. Accordingly, when a circuit pattern of the second metal pattern layer 132 is processed, a distance of the circuit pattern of the second metal pattern layer 132 may be narrower than a distance of a circuit pattern of the first metal pattern layer 111 by raising density. In this regard, the second semiconductor component 140 having a relatively smaller installation area that that of the first semiconductor component 120 may be installed on the second insulating substrate 130.

Also, as specifically illustrated in FIGS. 2A and 2B, the first insulating substrate 110 may be formed in such a way that at least one first upper metal pattern layer 111a, at least one first insulating layer 112, and at least one first lower metal pattern layer 111b are stacked or at least one first insulating layer 112 and at least one first upper metal pattern layer 111a are stacked.

Also, referring to FIG. 6, some areas of the second insulating layer 131 of the second insulating substrate 130 are spaced apart from the first upper metal pattern layer 111a of the first insulating substrate 110 by a regular distance D2, for example, 1 μm through 10 mm, so that a leakage current between the first upper metal pattern layer 111a and the second semiconductor component 140 installed on the second insulating substrate 130 may be blocked and thereby, electrical stability may be secured.

In addition, referring to FIG. 6, the entire thickness T3 of the second insulating substrate 130 is thinner than the entire thickness T4 of the first insulating substrate 110 so that the total area of a multi-layer substrate may be reduced to be compact and a spare space may be secured for stacking the second insulating substrate 130 on the first insulating substrate 110.

Moreover, after some areas of the first upper metal pattern layer 111a of the first insulating substrate 110 are removed, the second insulating substrate 130 may be stacked on the first insulating layer 112 which is exposed after being removed, and a circuit pattern of the second metal pattern layer 132 may be formed by etching.

Also, the second insulating layer 131 may be formed on the exposed first insulating layer 112 by using a screen printing method.

In addition, the first semiconductor component 120 and a part of the at least one second semiconductor component 140 described above are respectively bonded to the first insulating substrate 110 and the second insulating substrate 130 by using the same adhesive member interposed therebetween at the same temperature condition and thereby, cracks which may be generated due to a difference in a thermal expansive coefficient may be minimized. More specifically, when a plurality of second semiconductor components 140 are installed on the second insulating substrate 130, the semiconductor bare chip may be bonded to the second insulating substrate 130 by using a conductive epoxy adhesive member containing Ag interposed therebetween and the other second semiconductor components 140 may be bonded to the second insulating substrate 130 by soldering or sintering.

According to the semiconductor package and the method of manufacturing the same described above, the thickness of the upper substrate is formed to be relatively thin in a multi-layer substrate structure so that semiconductor components may be easily installed thereon, a distance of a circuit pattern in the upper substrate is formed to be narrow so that semiconductor components having a relatively small installation area may be installed, and the metal pattern layer of the lower substrate is spaced apart from the semiconductor components of the upper substrate to block leakage current so that electrical stability may be secured.

According to the present invention, the thickness of the upper substrate is formed to be relatively thin in a multi-layer substrate structure so that semiconductor components may be easily installed thereon, a distance of a circuit pattern in the upper substrate is formed to be narrow so that semiconductor components having a relatively small installation area may be installed, and the metal pattern layer of the lower substrate is spaced apart from the semiconductor components of the upper substrate to block leakage current so that electrical stability may be secured.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package comprising:
at least one first insulating substrate in which a first metal pattern layer and a first insulating layer are stacked;
at least one first semiconductor component installed on the first insulating substrate and electrically connected to the first metal pattern layer;
at least one second insulating substrate spaced apart from the first metal pattern layer by a regular distance, structurally bonded onto the first insulating layer of the first insulating substrate, and in which a second insulating layer and a second metal pattern layer are stacked;
at least one second semiconductor component installed on the second insulating substrate and electrically connected to the second metal pattern layer;
at least one lead frame terminal electrically connected to the first insulating substrate or the second insulating substrate; and
a housing covering the first semiconductor component, the second semiconductor component, and a part of the lead frame terminal,
wherein the thickness of the second metal pattern layer of the second insulating substrate is formed to be thinner than the thickness of the first metal pattern layer of the first insulating substrate.

2. The semiconductor package of claim 1, wherein the first insulating substrate is formed in such a way that at least one first upper metal pattern layer, at least one first insulating layer, and at least one first lower metal pattern layer are stacked or at least one first insulating layer and at least one first upper metal pattern layer are stacked.

3. The semiconductor package of claim 1, wherein the second insulating substrate comprises at least one second insulating layer.

4. The semiconductor package of claim 1, wherein the second metal pattern layer is partially or entirely covered with a third protective insulating layer except for the area of the second metal pattern layer where the second semiconductor component is installed.

5. The semiconductor package of claim 1, wherein the second insulating layer comprises a via hole penetrated thereinto and the second metal pattern layer comprises a second upper metal pattern layer and a second low metal pattern layer which are connected to each other by a metal via formed in the via hole.

6. The semiconductor package of claim 5, wherein the second semiconductor component is installed on the second upper metal pattern layer and a fourth insulating layer is formed between the first insulating layer and the second low metal pattern layer.

7. The semiconductor package of claim 6, wherein the second insulating layer and the fourth insulating layer are formed by using the same insulating material and thereby, are connected to each other.

8. The semiconductor package of claim 1, wherein an electrical connecting member which is mainly formed of Au, Cu, or Al is ultrasonic bonded to the second semiconductor component and the second metal pattern layer and are electrically connected to each other.

9. The semiconductor package of claim 1, wherein an electrical connecting member which is a metal ingredient is used to electrically connect the second semiconductor component to the second metal pattern layer but the electrical connecting member is a lead frame terminal prepared on the second semiconductor component.

10. The semiconductor package of claim 1, wherein the first semiconductor component and the second metal pattern layer are electrically connected to each other by an electrical connecting member.

11. The semiconductor package of claim 2, wherein the first upper metal pattern layer and the second metal pattern layer are electrically connected to each other by an electrical connecting member.

12. The semiconductor package of claim 1, wherein the lead frame terminal is bonded to the first insulating substrate or the second insulating substrate by soldering or sintering using a conductive adhesive interposed therebetween or by ultrasonic welding.

13. The semiconductor package of claim 2, wherein some areas of the second insulating substrate are spaced apart from the first upper metal pattern layer of the first insulating substrate by a regular distance.

14. The semiconductor package of claim 1, wherein the entire thickness of the second insulating substrate is thinner than the entire thickness of the first insulating substrate.

15. The semiconductor package of claim 1, wherein the first insulating substrate is partially or entirely exposed to the upper surface or the lower surface of the housing.

16. The semiconductor package of claim 15, wherein pin-fins are structurally connected to the first metal pattern layer included in the first insulating substrate which is exposed to the outside of the housing.

17. The semiconductor package of claim 1, wherein the first semiconductor component and a part of the at least one second semiconductor component are respectively bonded to the first insulating substrate and the second insulating substrate by using the same adhesive member interposed therebetween at the same temperature condition.

18. The semiconductor package of claim 2, wherein after some areas of the first upper metal pattern layer of the first insulating substrate are removed, the second insulating substrate is stacked on the first insulating layer which is exposed after being removed, and a circuit pattern of the second metal pattern layer is formed by etching.

19. The semiconductor package of claim 1, wherein the second insulating layer is formed on the first insulating layer by using a screen printing method.

20. A method of manufacturing a semiconductor package comprising:
preparing at least one first insulating substrate in which a first metal pattern layer and a first insulating layer are stacked;
structurally bonding at least one second insulating substrate in which a second insulating layer and a second metal pattern layer are stacked onto the first insulating layer of the first insulating substrate by being spaced apart from the first metal pattern layer by a regular distance; respectively installing at least one first semiconductor component and at least one second semiconductor component on the first insulating substrate and the second insulating substrate and electrically connecting the first semiconductor component to the first metal pattern layer and the second semiconductor component to the second metal pattern layer;
electrically connecting at least one lead frame terminal to the first insulating substrate or the second insulating substrate; and
packaging a housing to cover the first semiconductor component, the second semiconductor component, and a part of the lead frame terminal,
wherein the thickness of the second metal pattern layer of the second insulating substrate is thinner than the thickness of the first metal pattern layer of the first insulating substrate.
